(19) United States
(12) Patent Application Publication
(10) Pub. No.: US 2006/0270143 A1
(43) Pub. Date: Nov. 30, 2006

(54) Method for manufacturing contact structures for dram semiconductor memories

(76) Inventors: Matthias Goldbach, Dresden (DE); Clemens Fritz, Dresden (DE); Audrey Dupont, Dresden (DE)

Correspondence Address: DICKE, BILLIG & CZAJA, P.L.L.C., FIFTH STREET TOWERS, 100 SOUTH FIFTH STREET, SUITE 2250, MINNEAPOLIS, MN, 55402, US

(21) Appl. No.: 11/436,376

(22) Filed: May 18, 2006

(30) Foreign Application Priority Data
May 18, 2005 (DE) 10 2005 022 840.2

(51) Int. Cl. H01L 21/8244

(52) U.S. Cl. 438/238

(57) ABSTRACT

A method for manufacturing contact structures for DRAM semiconductor memories is disclosed. In one embodiment, contact openings are formed in a support area after execution of high-temperature processes for activating doping agents and repairing crystal defects. A low contact resistance between a conductive contact opening filling and an adjacent semiconductor substrate is achieved by forming a cobalt silicide or nickel silicide.

### CROSS-REFERENCE TO RELATED APPLICATIONS

This Utility Patent Application claims priority to German Patent Application No. DE 10 2005 022 840.2 filed on May 18, 2005, which is incorporated herein by reference.

### FIELD OF THE INVENTION

The present invention relates to a method for manufacturing contact structures in a cell field area and a support area of DRAM semiconductor memories.

### BACKGROUND

DRAMs (Dynamic Random Access Memory, memory with direct access) have a cell field, in which DRAM memory cells for storing an electric charge determining a data content of the respective memory cell are arranged, and a support area, which in particular holds components for electronic circuits for activating individual memory cells. The support area has, in particular, p-channel and n-channel MOSFETs (metal oxide semiconductor field-effect transistors).

The DRAM memory cells each include a memory backup capacitor for storing the electric charge and a selection transistor with which a connection of an energy-storage electrode of the memory backup capacitor to a data line can be established for writing or reading of charge on the memory backup capacitor. The memory backup capacitors are formed either as stack or trench capacitors. Trench capacitors are put in a semiconductor substrate from a substrate surface, while multilayer or stack capacitors are provided above the substrate surface in a wiring area of the DRAM.

The selection transistors are formed as field-effect transistors with an active area with a source and a drain area, which are distanced from each other by a channel area. Above the channel area a gate electrode distanced by a gate dielectric is provided, via whose potential a conductivity of the channel area can be set by field-effect. A conducting connection can thus be established between the source and the drain for writing or reading charges to or from the memory backup capacitor. If the gate electrode is held at a potential, so that no conducting channel area is formed, the charge is held on the memory backup capacitor and only flows off through leakage currents in the course of time.

The selection transistors of the memory cell field are usually formed as n-channel field-effect transistors. The circuits for the support area generally provide both n-channel and p-channel field-effect transistors.

For the formation of the field-effect transistors in the selection and support area, a gate dielectric is formed on a substrate surface of the semiconductor substrate, after which a gate conductor material is applied and a structuring of the gate conductor material or the gate conductor materials into gate conductor structures occurs. In this case the substrate surface is exposed in areas between the gate conductor structures, thereby enabling the placing by implantation of doping agents in the semiconductor substrate for the formation for example of source/drain areas or further areas determining the properties of the transistors, such as for example LDD (Lightly Doped Drain) areas to avoid avalanche breakdown.

The properties of the transistors are essentially determined by the doping profile in the active area as well as by the crystal quality. Thus for example the doping profile influences a leakage current, or short-channel effects such as hot electrons which are decisive for the reliability of the DRAM. The crystal quality affects in particular the charge conservation (data retention) properties of the memory backup capacitor. A disturbance caused in the crystal by defects such as e.g., displacements or vacant sites increases the leakage current of the memory backup capacitor by increased recombination of minority and majority charge carriers on recombination centers attributable to the defects.

In order to keep down the leakage current and hence the defect concentration in the active area to achieve the longest possible charge conservation time, it is necessary to repair defects brought into the crystal structure of the silicon in the ion implantation of a doping agent, i.e., to improve the crystal quality afterwards. Used for this are high-temperature repair processes, such as for example a final furnace anneal, in which displacements are restructured and interstitial atoms are returned by diffusion to correct places in the crystal lattice.

It is usual when manufacturing the contact structures in the cell field area and support area, first to open an insulating layer covering the surface of the semiconductor substrate in the area of bit line contacts to be formed, to execute a CB implantation of doping agents, then in the support area to form contact openings for the connection of the p-channel field-effect transistors and the n-channel field-effect transistors and after masking of the openings for the connection of the n-channel transistors to implant doping agents of the p conduction type into the semiconductor substrate in the area of the contact openings of the p-channel transistors. This implantation serves to lower the contact resistance between the source and drain areas formed in the semiconductor substrate with the base (usually formed as titanium silicide) of a conductive contact opening filling. Since titanium silicide dissolves doping agents of the p loading type, especially boron, the contact resistance to the corresponding source or drain area is thereby increased, as less boron is available in the semiconductor substrate bordering the titanium silicide. For this reason, this implantation, also called CSP (Contact Support p-type) Implantation, is used for supplying additional doping agents of the p conduction type, in order to keep the contact resistance as low as possible. The implantation is followed by high-temperature steps for activating the doping agents and for repairing the defects caused by the implantation in the crystal lattice.

However, a disadvantage is that the high-temperature steps lead to a deformation especially of the contact openings formed in the support area. The high-temperature processes can cause the contact openings to tilt or roundings to appear on their surface, or the insulating layer can show a curvature in the area between adjacent contact openings. After the formation of a conductive material, preferably tungsten, on the insulating layer and the removal of the conductive material on the surface by CMP (chemical mechanical polishing), conductive material can remain in unwanted places, so that short circuits occur for example between tilted contact openings, or conductive material can appear in the roundings with adjacent conducting tracks. It can similarly lead to the absence of an envisaged connection on a particular conducting track, if as a result of tilting a contact opening is lateral to a particular conducting track serving for the connection of this contact opening, and not below it.

For these and other reasons there is a need for the present invention.

### SUMMARY

The present invention provides a method for manufacturing contact structures for DRAM semiconductor memories, in which contact openings are formed in a support area after execution of high-temperature processes for activating doping agents and repairing crystal defects. A low contact resistance between a conductive contact opening filling and an adjacent semiconductor substrate is achieved by forming a cobalt silicide or nickel silicide.

### BRIEF DESCRIPTION OF THE DRAWINGS

The accompanying drawings are included to provide a further understanding of the present invention and are incorporated in and constitute a part of this specification. The drawings illustrate the embodiments of the present invention and together with the description serve to explain the principles of the invention. Other embodiments of the present invention and many of the intended advantages of the present invention will be readily appreciated as they become better understood by reference to the following detailed description. The elements of the drawings are not necessarily to scale relative to each other. Like reference numerals designate corresponding similar parts.

The invention and in particular certain features, aspects and advantages of the invention will be elucidated with the help of the following detailed description in combination with the accompanying drawings.

FIG. 1a-c illustrate contact openings in the support area before and after high-temperature processes according to a method for forming contact structures.

FIG. 2 illustrates one embodiment for the manufacturing of contact structures according to the invention.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments of the present invention can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

The present invention provides a method for manufacturing semiconductor memories and contact structures for DRAM semiconductor memories.

According to one embodiment of the invention, method for manufacturing contact structures for DRAM semiconductor memories includes the following process:

Provision of a preprocessed semiconductor substrate, which has a cell field area and a support area on a surface, formation of an insulating layer on the surface, formation of contact openings extending to the surface in the cell field area by removal of the insulating layer (CB contact openings, CB: contact bitline), implantation of doping agents in the semiconductor substrate in the area of the CB contact openings, execution of a high-temperature activation process to activate the doping agents, execution of a high-temperature repair process to repair the crystal defects in the semiconductor substrate, formation of contact openings extending to the surface in the support area by etching of the insulating layer (CS etching), formation of a metallic layer on the surface, formation of one or more covering layers on the metallic layer, and execution of an annealing process and filling of the contact openings in the cell field area and the support area with a conductive material.

The preprocessed semiconductor substrate has gate conductor structures insulated by a gate dielectric from the semiconductor surface, these serving to set the channel conductance of the transistors in the cell field area as well as in the support area. The preprocessed semiconductor substrate likewise has distributions of doping agents, which were put in during preceding implantation processes. These distributions of doping agents are used for definition of the electrical properties of the transistors, and can serve for example as source/drain areas or LDD areas. The insulating layer serves in particular for electrical insulation of the components formed in the semiconductor substrate from a wiring area formed above the semiconductor substrate, this wiring area usually having metallically executed conducting tracks, which in the area of contact openings are electrically connected to the components in the semiconductor substrate.

CB contact openings, which are defined by removal of the insulating layer in the cell field area, serve for the connection of the selection transistors of the memory cells to bit lines. For the removal of the insulating layer of the CB contact openings, an anisotropic etching process for example is suitable, in particular an RIE (Reactive Ion Etching) etching process, in which the areas of the insulating layer which are not to be etched are covered before the etching process with an applied etch resist layer. To lower the contact resistance between the bitline contact and the semiconductor substrate, a CB implantation of doping agents is executed to raise a doping agent concentration on the surface of the semiconductor substrate in the area of the CB contact openings. Since the contact resistance on the surface of the semiconductor substrate to the usually metallically formed contact opening filling is reduced with increasing doping agent concentration, a lowering of the contact resistance is achieved by the CB implantation.

In this stage of the manufacturing process, only contact openings in the cell field area are formed. The high-temperature activation process serves for activation of the doping agents, for example as a Junction Activation Anneal or Spike Anneal to a temperature range of about 950° C. to 1050° C. The high-temperature activation process can also be executed as an RTP (Rapid Thermal Processing) process. Without repair of the crystal defects, the crystal structure in the semiconductor substrate disturbed by the doping agent implantations would lead to such high leakage currents that the charge conservation time of the memory backup capacitor of a DRAM memory cell would take on unacceptably low values. The high-temperature repair process therefore serves for repairing the crystal defects and thus for reducing the leakage currents, and thus extending the charge conservation time of the memory backup capacitors. The high-temperature repair process usually takes place at lower temperatures than the high-temperature activation process, and is in the range 750° C. to 850° C., for example.

For the formation of contact openings in the support area (CS contact openings) an etching of the insulating layer is used (CS etching). Just as for the formation of the CB contact openings, an anisotropic etching is suitable here, in particular a dry-chemical RIE etching process. The metallic layer subsequently formed on the surface in the cell field area and support area covers the surface and thus in particular also side walls and base areas of the contact openings. Suitable metallic layers such as a cobalt layer or a nickel layer, which connect to the semiconductor substrate in the base area of the contact holes, are outstandingly suited to forming a silicide with especially favorable properties with regard to the low contact resistance, since in particular in the formation of a CoSiₓ (cobalt silicide) or NiSiₓ (nickel silicide) adjacent to a boron doped semiconductor area of the p conduction type in comparison to the commonly used TiSi_{K} (titanium silicide) no boron is dissolved, so that after the formation of the metal silicide a comparatively high doping agent concentration remains, which results in a comparatively low contact resistance. The one or more covering layers on the metallic layer are suitable for example as adhesion agents, diffusion barriers or as a protective layer with regard to subsequent process steps. The annealing process takes place in the temperature range from about 400° C. to 550° C., for example.

In one embodiment, the covering layer has a Ti layer and a TiN layer, and the annealing process serves also, among other things, for forming the metal silicide.

The metallic layer is formed as a cobalt layer. This leads to the advantageous properties relating to contact resistance as mentioned above.

In one embodiment, the covering layer is formed from TiN or Ti and afterwards, and before the annealing process, to execute the processes annealing with an RTP process, removal of the covering layer and the metallic layer formed as a cobalt layer by etching, annealing with a further RTP process and formation of a TiN layer on the surface. For the formation of the covering layer from TiN or Ti, a sputtering method is suitable, for example. The RTP process and the further RTP process serve for formation of the cobalt silicide in the area between the cobalt layer and the adjacent semiconductor substrate. The TiN layer formed on the surface after the removal of the covering layer and the annealing with the further RTP process has favorable properties in particular as a diffusion barrier with a high electromigration resistance.

In one embodiment, the covering layer and the Co layer are removed by etching with SC-2 solution or with SC-1 solution and SC-2 solution or with Piranha solution. The SC-1 solution is also known as Huang A solution. The SC-2 solution is also known as Huang B solution and serves for dissolving metals and ions especially by complexing. This solution is thus suitable for removing cobalt or Ti, for example. In etching with Piranha solution (also called SPM solution), sulphuric acid and hydrogen peroxide in particular are used.

In one embodiment, the covering layer is formed from TiN or Ti, and subsequently and before the annealing process an RTP process is executed, followed by the formation of a TiN layer on the surface. The RTP process serves especially for forming the cobalt silicide.

In one embodiment, the RTP process is executed in the temperature range from about 400° C. to 550° C. for a period of about 5 sec to 60 sec. Desired properties with regard to the low-impedance contact resistance can hereby be achieved with the metallic layer formed as a cobalt layer.

With the metallic layer formed as a cobalt layer, the further RTP process is executed in the temperature range from about 600° C. to 800° C. for a period of about 5 sec to 60 sec. This further RTP process serves for a further reduction of the contact resistance. It should be pointed out at this stage that the further RTP process more trivially reduces the contact resistance compared to the RTP process executed in the temperature range from about 400° C. to 550° C. The metallic layer is advantageously formed as a nickel layer. Just as a cobalt layer, this leads to advantageous properties relating to the contact resistance.

In one embodiment, the covering layer is formed from TiN or Ti and afterwards, and before the annealing step, to execute the processes annealing with an RTP step, removal of the covering layer and the metallic layer formed as a nickel layer by etching, annealing with a further RTP process and formation of a TiN layer on the surface. For the formation of the covering layer from TiN or Ti, a sputtering method is suitable, for example. The RTP process and the further RTP process serve for formation of the nickel silicide in the area between the nickel layer and the adjacent semiconductor substrate. The TiN layer formed on the surface after the removal of the covering layer and the annealing with the further RTP process has favorable properties in particular as a diffusion barrier with a high electromigration resistance.

The covering layer and the Ni layer are removed by etching with SC-2 solution or with SC-1 solution and SC-2 solution or with Piranha solution. The SC-1 solution is also known as Huang A solution. The SC-2 solution is also known as Huang B solution and serves for dissolving metals and ions especially by complexing. In etching with Piranha solution (also called SPM solution), sulphuric acid and hydrogen peroxide in particular are used. The SPM solution is especially suitable for etching of nickel, for example at 65° C. for 10 min.

In one embodiment, the covering layer is formed from TiN or Ti, and subsequently and before the annealing process an RTP process is executed, followed by the formation of a TiN layer on the surface. The RTP process serves especially for forming the nickel silicide.

In one embodiment the RTP process is executed in the temperature range from about 250° C. to 350° C. for a period of about 5 sec to 60 sec. Especially properties with regard to the low-impedance contact resistance can hereby be achieved with the metallic layer formed as a nickel layer.

With the metallic layer formed as a nickel layer, the further RTP process is executed in the temperature range from about 380° C. to 500° C. for a period of about 5 sec to 60 sec. This further RTP process serves for a further reduction of the contact resistance. It should be pointed out at this stage that the further RTP process more trivially reduces the contact resistance compared to the RTP process executed in the temperature range from about 250° C. to 350° C.

In one embodiment, the covering layer is formed with a layer thickness in the range of about 5 to 80 nm. A sputter process advantageously serves for forming the covering layer. In this sputter process there is a deposition rate dependent on the aspect ratio.

In a further embodiment, the insulating layer is formed as silicate glass and a subsequent reflow process is executed. The silicate glass is a BPSG (boron-phosphosilicate glass) or a BSG (boron-silicate glass), for example. The reflow process serves to run and thus smooth the surface of the silicate glass, the temperature during the reflow process being determined essentially by the boron content influencing the flow properties of SiO₂. Mechanical tensions in the silicate glass are likewise smoothed out by the flow.

In a preferred embodiment, tungsten is used as conductive material for filling the contact openings. Tungsten in particular offers advantages, as it has high temperature stability, can be deposited conformally by CVD (Chemical Vapor Deposition), and has a low layer resistivity.

It is advantageous to develop the metallic layer with a thickness in the range of about 10 to 50 nm.

The invention is thus distinguished, among other things, by the fact that the formation of the CS contact openings in the support area occurs after execution of the high-temperature processes for activating the implanted doping agents and repairing the crystal lattice, and that in the support area an implantation of doping agents to improve the contact resistance of the p-channel field-effect transistors can be avoided by forming a cobalt silicide or nickel silicide which reduces the contact resistance.

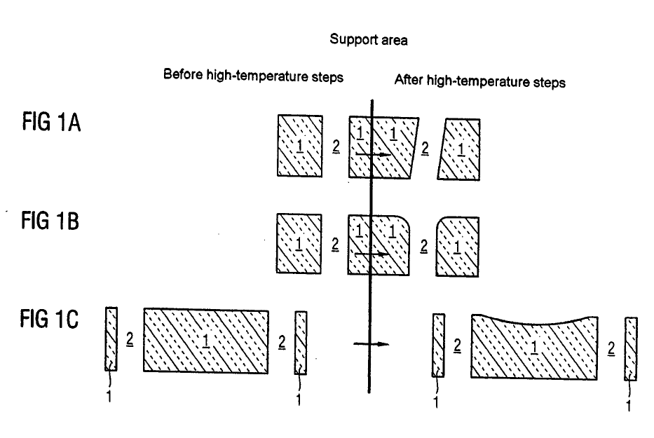

The FIGS. 1a to 1c, in the left part of the figure, illustrate cross-section views of an insulating layer 1, preferably formed as a BPSG, with contact openings 2. Only the relevant parts useful for understanding the contact structure in the support area are illustrated. On the formation of the contact openings 2 in the support area and in the cell field area which is not illustrated, in this manufacturing method doping agents are put by implantation into the semiconductor substrate (CB implantation) via the contact openings 2 in the cell field area which is not illustrated, in order to keep the contact resistance between a conductive contact filling material and the adjacent semiconductor substrate as low as possible. Since this implantation causes crystal defects in the semiconductor substrate and the doping agents have to be activated, this implantation is followed by a Junction Activation Anneal and a Final Furnace Anneal, which serve to activate the doping agents and to repair the crystal defects, and are shown in FIG. 1 as high-temperature steps.

The high-temperature processes lead to deformations of the insulating layer 1. Thus for example, as shown in the right part of FIG. 1a, tiltings of the contact openings 2 appear. Roundings can likewise occur in an upper part of the contact openings 2 in the support area: see FIG. 1b. FIG. 1c illustrates a curvature formed in the insulating layer between adjacent contact openings 2.

In the filling of the contact openings 2 with tungsten, a surface of the insulating layer 1 is initially also covered according to the method. To remove the tungsten on the surface outside the contact openings 2, the tungsten deposition is followed by execution of a CMP step, which however leaves residues of tungsten in areas not defined for the provided contact openings 2. Such tungsten residues are found for example within the curves in the insulating layer 1 (see FIG. 1c), in the area of the roundings of the contact openings 2 (see FIG. 1b) and also on points shifted laterally to the base of the contact opening 2 on the upper side of the tilted contact opening 2 (see FIG. 1a).

In the formation of a first metallization level, short circuits can occur between contact structures and conducting tracks of the first metallization level, for one thing. It is likewise possible (see FIG. 1a) that taking into account process tolerances, a conducting track adjusted in relation to the base area of the contact opening 2 for the connection of the semiconductor substrate 3 is shifted laterally to the tilted contact opening 2 and therefore no longer makes contact with this, which situation corresponds to a line opening or open connection.

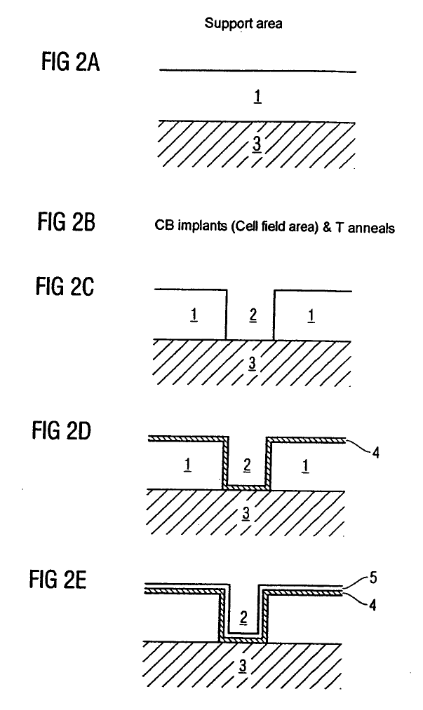

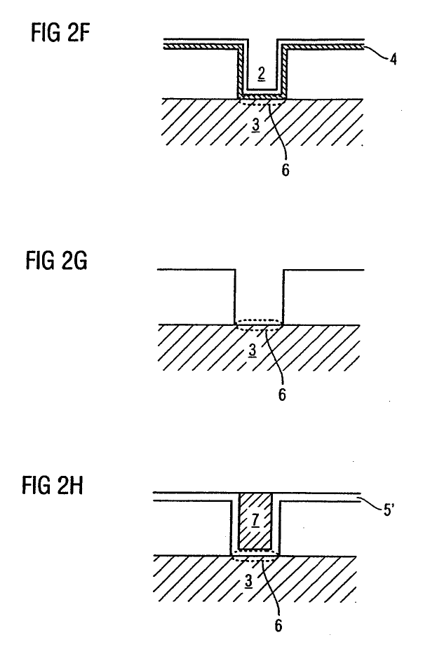

FIG. 2 illustrates in the subfigures a to h schematic cross-section views during successive process stages in the manufacture of the contact structures in the support area. In FIG. 2a, the insulating layer 1 was applied to a semiconductor substrate 3. In the process process noted in FIG. 2b, a CB implantation takes place in the cell field area which is not illustrated, as well as those to activate the doping agents and to repair the crystal defects put in the crystal lattice in the implantation, by high-temperature processes such as Junction Activation Anneal and Final Furnace Anneal. FIG. 2b illustrates a CS contact opening 2 preferably formed by etching of the insulating layer 1 as far as a surface of the semiconductor substrate 3. In FIG. 2b, side walls and a base area of the contact opening 2 and also the insulating layer 1 are covered by a metallic layer 4 formed as a Co layer (cobalt layer). It is explicitly pointed out here that as well as cobalt, nickel in particular is suitable as a metallic layer. However, the description of the embodiment uses a cobalt layer as an example. The Co layer 4 likewise covers the cell field area (not shown). Subsequently, as illustrated in FIG. 2e, a covering layer 5 of TiN is formed on the Co layer. An annealing process serves for forming a cobalt silicide (CoSiₓ) 6 in the base area of the contact opening 2, leading to the cross-section view shown in FIG. 2f. After the forming of the CoSiₓ 6, the covering layer and the Co layer 4 are removed by etching, so that the CoSiₓ 6 remains in the base area of the contact opening 2. The subsequent processes for forming the contact structures correspond to the process formation of a covering layer from TiN and filling of the contact openings 2 with a conductive contact opening filling 7 consisting of tungsten.

The CoSiₓ thus serves to lower the contact resistance between the contact opening filling and the adjacent semiconductor substrate 3. An additional implantation, in particular to form a low contact resistance for the connection of p-channel field-effect transistors can thus be omitted because of the advantageous properties of the CoSiₓ, so that it becomes possible to bring forward the high-temperature processes before the formation of the contact openings 2 in the support area. Consequently, temperature-related deformations of the contact openings 2 can be avoided in the support area.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A method for manufacturing a semiconductor memory comprising:
providing a preprocessed semiconductor having a semiconductor substrate, which has a cell field area and a support area on a surface;
forming an insulating layer on the surface;
forming contact openings extending to the surface in the cell field area by removal of the insulating layer;
forming contact openings extending to the surface in the support area by an etching of the insulating layer; and
forming a metallic layer on the surface.

2. The method of claim 1, comprising:
forming one or more covering layers on the metallic layer; and
executing an annealing process and filling of the contact openings in the cell field area and in the support area with a conductive material.

3. The method according to claim 2, comprising wherein the covering layer consists of a Ti layer and a TiN layer.

4. The method according to claim 2, comprising wherein the metallic layer is formed as a cobalt layer.

5. The method according to claim 3, comprising wherein the covering layer is formed from TiN or Ti, and subsequently and before the annealing process, executing the following process comprising:
annealing with an RTP process;
removing the covering layer and the metallic layer formed as a cobalt layer by etching;
annealing with a further RTP process; and
forming a TiN layer on the surface.

6. The method according to claim 4, comprising wherein the covering layer and the metallic layer formed as a cobalt layer are removed with an SC-2 solution or with an SC-1 solution and an SC-2 solution or with a Piranha solution.

7. The method according to claim 3, comprising wherein the covering layer is formed from TiN or Ti, and subsequently and before the annealing process, executing the process comprising:
annealing with an RTP process; and
forming a TiN layer on the surface,

8. The method according to claim 1, comprising wherein the metallic layer is formed as a nickel layer.

9. A method for manufacturing contact a DRAM semiconductor memory having a contact structure comprising:
providing a preprocessed semiconductor substrate, which has a cell field area and a support area on a surface;
forming an insulating layer on the surface;
forming contact openings extending to the surface in the cell field area by removal of the insulating layer;
implanting doping agents into the semiconductor substrate in the area of the contact openings in the cell field area;
executing a high-temperature activation process to activate the doping agents;
executing a high-temperature repair process to repair crystal defects in the semiconductor substrate;
forming contact openings extending to the surface in the support area by an etching of the insulating layer;
forming a metallic layer on the surface;
forming one or more covering layers on the metallic layer; and
executing an annealing process and filling of the contact openings in the cell field area and in the support area with a conductive material.

10. The method according to claim 8, comprising wherein the covering layer consists of a Ti layer and a TiN layer.

11. The method according to claim 8, comprising wherein the metallic layer is formed as a cobalt layer.

12. The method according to claim 10, comprising wherein the covering layer is formed from TiN or Ti, and subsequently and before the annealing process the following processes are executed:
annealing with an RTP step;
removing the covering layer and the metallic layer formed as a cobalt layer by etching;
annealing with a further RTP step; and
forming a TiN layer on the surface.

13. The method according to claim 11, comprising wherein the covering layer and the metallic layer formed as a cobalt layer are removed with an SC-2 solution or with an SC-1 solution and an SC-2 solution or with a Piranha solution.

14. The method according to claim 10, comprising wherein the covering layer is formed from TiN or Ti, and subsequently and before the annealing process the following processes are executed:
annealing with an RTP step; and
formation of a TiN layer on the surface.

15. A The method according to one of claim 11, comprising wherein the RTP process is executed in the temperature range from about 400° C. to 550° C. for a period of about 5 to 60 seconds.

16. The method according to claim 11, comprising wherein the further RTP process is executed in the temperature range from about 600° C. to 800° C. for a period of about 5 to 60 seconds.

17. The method according to claim 8, comprising wherein the metallic layer is formed as a nickel layer.

18. The method according to claim 16, comprising wherein the covering layer is formed from TiN or Ti, and subsequently and before the annealing process the following processes are executed:
annealing with an RTP step;
removing the covering layer and the metallic layer formed as a nickel layer by etching;
annealing with a further RTP step; and
forming a TiN layer on the surface.

19. The method according to claim 17, comprising wherein the covering layer and the metallic layer formed as a nickel layer are removed with an SC-2 solution or with an SC-1 solution and an SC-2 solution or with a Piranha solution.

20. The method according to claim 16, comprising wherein the covering layer is formed from TiN or Ti, and subsequently and before the annealing process the following processes are executed:
annealing with an RTP step; and
forming a TiN layer on the surface.

21. The method according to one of claim 17, comprising wherein the RIP process is executed in the temperature range from about 250° C. to 350° C. for a period of about 5 to 60 seconds.

22. The method according to claim 17, comprising wherein the further RTP process is executed in the temperature range from about 380° C. to 500° C. for a period of about 5 to 60 seconds.

23. The method according to claim 8, comprising wherein the covering layer is formed with a layer thickness in the range of about 5 to 80 nm.

24. The method according to claim 8, comprising wherein the insulating layer is formed as silicate glass and a subsequent reflow process is executed.

25. The method according to claim 8, comprising-wherein the conductive material for filling the contact openings is tungsten.

26. The method according to claim 8, comprising wherein the metallic layer is formed with a thickness in the range of about 10 to 50 mm.

27. A method for manufacturing a semiconductor memory comprising:
providing a preprocessed semiconductor having a semiconductor substrate, which has a cell field area and a support area on a surface;
means for forming an insulating layer on the surface;
means for forming contact openings extending to the surface in the cell field area by removal of the insulating layer;
means for forming contact openings extending to the surface in the support area by an etching of the insulating layer, and
means for forming a metallic layer on the surface.
